(19) United States
(12) Patent Application Publication
(10) Pub. No.: US 2025/0132151 A1
(43) Pub. Date: Apr. 24, 2025

(54) SEMICONDUCTOR LAMINATE, SEMICONDUCTOR ELEMENT, AND SEMICONDUCTOR LAMINATE PRODUCTION METHOD

(71) Applicant: SUMITOMO CHEMICAL COMPANY, LIMITED, Tokyo (JP)

(72) Inventors: Hajime FUJIKURA, Hitachi-shi (JP); Fuminasa HORIKIRI, Hitachi-shi (JP); Taichiro KONNO, Hitachi-shi (JP); Takeshi KIMURA, Hitachi-shi (JP); Shota KANEKI, Hitachi-shi (JP)

(73) Assignee: SUMITOMO CHEMICAL COMPANY, LIMITED, Tokyo (JP)

(21) Appl. No.: 18/918,736

(22) Filed: Oct. 17, 2024

(30) Foreign Application Priority Data
Oct. 19, 2023 (JP) 2023-180002

(51) Int. Cl. H01L 21/02; C30B 25/18; C30B 29/40; C30B 29/68; C30B 33/02; H01L 29/04; H01L 29/16; H01L 29/20; H01L 29/267; H01L 29/778

(52) U.S. Cl. CPC H01L 21/02378; C30B 25/18; C30B 29/403; C30B 29/406; C30B 29/68; C30B 33/02; H01L 21/0254; H01L 21/02694; H10D 62/405; H10D 62/82; H10D 62/8325; H10D 62/8503; H10D 30/475

(57) ABSTRACT

To obtain a high-quality semiconductor laminate and a high-quality semiconductor element. [Solution] Provided is a semiconductor laminate including a substrate that includes silicon carbide and has a main surface, a first layer that is provided on the main surface of the substrate and includes an aluminum nitride crystal, a second layer that is provided on the first layer and includes a crystal of any of aluminum gallium nitride, aluminum indium nitride, and aluminum indium gallium nitride, and a third layer that is provided on the second layer and includes a gallium nitride crystal, in which the first layer has tensile strain in a direction along the main surface at 27° C.

### TECHNICAL FIELD

The present disclosure relates to a semiconductor laminate, a semiconductor element, and a semiconductor laminate production method.

### BACKGROUND ART

Group III nitride-based high electron mobility transistors (HEMTs) are widely used as power amplifiers for cell phone base stations (for example, Patent Document 1). In the case of the group III nitride-based HEMTs, power that can be input per element can be significantly increased as compared to Si-based devices that have been used conventionally. As a result, a reduction in the size of base stations can be achieved and installation costs can be significantly reduced.

### PRIOR ART DOCUMENT

### Patent Document

Patent Document 1: Japanese Patent Laid-Open Publication No. 2017-228642

### SUMMARY

### Problems to be Solved by the Disclosure

An objective of the present disclosure is to obtain a high-quality semiconductor laminate and a high-quality semiconductor element.

### Means for Solving Problem

According to an aspect of the present disclosure, provided is a semiconductor laminate, including:
a substrate including silicon carbide and having a main surface,
a first layer provided on the main surface of the substrate, the first layer including an aluminum nitride crystal,
a second layer provided on the first layer, the second layer including a crystal of any of aluminum gallium nitride, aluminum indium nitride, and aluminum indium gallium nitride, and
a third layer provided on the second layer, the third layer including a gallium nitride crystal;
in which the first layer has tensile strain in a direction along the main surface at 27° C.

According to another aspect of the present disclosure,
provided is a semiconductor element including, as at least a part of an active layer, the third layer in the semiconductor laminate according to the above-mentioned aspect.

According to still another aspect of the present disclosure, provided is a semiconductor laminate production method, including:
(a) preparing a substrate including silicon carbide and having a main surface,
(b) growing, on the main surface of the substrate, a first layer including an aluminum nitride crystal,
(c) subjecting the first layer to an annealing treatment,
(d) growing, on the first layer, a second layer including a crystal of any of aluminum gallium nitride, aluminum indium nitride, and aluminum indium gallium nitride, and
(e) growing, on the second layer, a third layer including a gallium nitride crystal;
in which, in (c), the dislocation density in the main surface of the first layer is decreased through the annealing treatment of the first layer to be smaller than the dislocation density in the main surface of the first layer immediately after (b).

### Advantage of Disclosure

According to the present disclosure, a high-quality semiconductor laminate and a high-quality semiconductor element can be obtained.

### BRIEF DESCRIPTION OF DRAWINGS

FIG. 1 is a schematic cross-sectional view illustrating a semiconductor laminate according to an embodiment of the present disclosure.

FIG. 2 is a schematic cross-sectional view illustrating a semiconductor element according to an embodiment of the present disclosure.

FIG. 3 is a flow chart of a semiconductor laminate production method and a semiconductor element production method according to an embodiment of the present disclosure.

FIG. 4A is a graph showing the full width at half maximum of (0002) diffraction from an electron transport layer in X-ray rocking curve measurement with respect to the Al composition ratio in an intermediate layer.

FIG. 4B is a graph showing the full width at half maximum of (0002) diffraction from the electron transport layer in X-ray rocking curve measurement with respect to the (0002) diffraction angle 2θ of the electron transport layer.

FIG. 5A is a graph showing the full width at half maximum of (0002) diffraction from the electron transport layer in X-ray rocking curve measurement with respect to the thickness of the electron transport layer.

FIG. 5B is a graph showing the full width at half maximum of (10-12) diffraction from the electron transport layer in X-ray rocking curve measurement with respect to the thickness of the electron transport layer.

### DETAILED DESCRIPTION

### Findings Obtained by Inventors

First, findings obtained by the present inventors will be described.

Silicon carbide (SiC), aluminum nitride (AlN), and gallium nitride (GaN) constituting a group III nitride-based HEMT have linear expansion coefficients, a-axis lengths (lattice constants in the a-axis direction), and c-axis lengths (lattice constants in the c-axis direction) shown in Table 1 below in a bulk state, respectively. Note that the linear expansion coefficients greatly differ according to temperature and are also dependent on the concentration of a dopant, and thus have a high degree of uncertainty. However, the magnitude relationship among the absolute values of the linear expansion coefficients (6H—SiC<GaN<AlN) is certain.

TABLE 1

| | Linear expansion | | |
|---|---|---|---|
| | coefficient | a-axis length | c-axis length |
| | (×10⁻⁶/K) | (Å) | (Å) |
| 6H-SiC | 4~5 | 3.0806 | 15.117 |
| AlN | 6.4~6.7 | 3.112 | 4.982 |
| GaN | 5.5~6.0 | 3.189 | 5.1866 |

The crystal quality is affected by the lattice constant of each crystal, the linear expansion coefficient of each crystal, and the state of each layer depending on temperature in a laminate for producing an HEMT.

A conventional laminate for producing an HEMT, the laminate of Patent Document 1, and a laminate of the present disclosure found by the inventors are now compared with reference to Table 2 below.

TABLE 2

| | Conventional | Patent Document 1 | Present disclosure |
|---|---|---|---|
| Base layer | AlN: high | AlN: high | AlN: low |
| | dislocation | dislocation density | dislocation density |
| | density | | |
| Intermediate | | AlGaN: high | AlGaN: low |
| layer | | dislocation density | dislocation density |
| Electron | GaN: high | GaN: high | GaN: low |
| transport layer | dislocation | dislocation density | dislocation density |
| | density | | |

### Conventional Laminate

The conventional laminate includes a SiC substrate, an AlN layer as a base layer, a GaN layer as an electron transport layer, and an aluminum gallium nitride (AlGaN) layer as an electron supply layer in this order.

In a conventional AlN layer growth step, for example, the AlN layer is grown on the SiC substrate to a thickness of, for example, 100 nm or less. Since the layer is grown on a heterogeneous substrate, the resulting AlN layer has poor crystallinity with a very high threading dislocation density in the order of 10⁹ to 10¹⁰ cm⁻². It has been known that, with the conventional method, the dislocation density of the AlN layer is not easily improved even when the thickness of the AlN layer is increased to several μm.

In a conventional GaN layer growth step, the GaN layer is grown on the above mentioned AlN layer with a high dislocation density. Therefore, the resulting GaN layer also has poor crystallinity with a dislocation density in the order of 10⁹ cm⁻² or more.

Further, in the conventional GaN layer growth step, since the GaN layer having a relatively large lattice constant is grown on the AlN layer having a relatively small lattice constant, compressive strain is applied to the GaN layer during the growth of the GaN layer. Therefore, a dislocation due to crystal strain is newly generated in the GaN layer. As a result, the crystallinity of the GaN layer is decreased in the conventional laminate.

Even with the conventional method, when the thickness of the GaN layer is set to 2 μm or more, dislocations are decreased as the GaN layer grows thicker. As a result, the GaN layer has good crystallinity with a dislocation density in the order of 10⁸ cm⁻² or less. However, when the thickness of the GaN layer is less than 2 μm, it has been difficult to make the dislocation density of the GaN layer to the order of 10⁸ cm⁻² or less.

### Laminate of Patent Document 1

The laminate of Patent Document 1 has a SiC substrate, an AlN layer as a base layer, a first AlGaN layer as an intermediate layer, a GaN layer as an electron transport layer, and a second AlGaN layer as an electron supply layer in this order.

Since no particular dislocation density reduction treatment is carried out for the AlN layer, it is presumed that the AlN layer has a very high threading dislocation density such as a dislocation density in the order of 10⁹ to 10¹⁰ cm⁻² and has poor crystallinity, also in Patent Document 1. Since no particular measures for decreasing the dislocation density are taken also in the growth of the AlGaN layer and the GaN layer above the AlN layer, it is considered that the GaN layer as the electron transport layer also has poor crystallinity with a dislocation density in the order of 10⁹ cm⁻² or more.

In Patent Document 1, the lattice constant of the AlGaN layer is converted to a value close to the lattice constant of a bulk GaN crystal by doping the AlGaN layer with impurities. This conversion is considered to aim at suppressing generation of a new dislocation in the GaN layer due to lattice strain. However, as mentioned above, the dislocation density of the AlN layer serving as the base layer and the dislocation density of the AlGaN layer inheriting the dislocation density of the AlN layer are inherently high. Therefore, it is considered that even when the AlGaN layer is doped with impurities, the dislocation density of the GaN layer is maintained at a high value in the order of 10⁹ cm⁻² or more.

Further, Patent Document 1 (paragraph 0016) indicates that the lattice constant of the entire GaN layer is substantially equal to the lattice constant of a bulk GaN crystal; that is, the GaN layer undergoes lattice relaxation at room temperature. That is, lattice relaxation of the GaN layer at room temperature corresponds to application of compressive strain to the GaN layer at the growth temperature of the GaN layer on the basis of the magnitude relationship of the linear expansion coefficients and the absolute values thereof mentioned above.

Therefore, in the GaN layer growth step, a dislocation due to crystal strain is newly generated in the GaN layer. As a result, it is considered that the crystallinity of the GaN layer is decreased in the laminate of Patent Document 1.

### Outline of Laminate of Present Disclosure

The present inventors have studied, as a laminate for producing an HEMT, a semiconductor laminate having a SiC substrate, an AlN layer subjected to an annealing treatment as a base layer, an AlGaN layer as an intermediate layer, a GaN layer as an electron transport layer, and an AlGaN layer as an electron supply layer in this order.

As a result of intensive studies, the present inventors have successfully found the following configuration.

In the configuration of the present disclosure, the dislocation density of the AlN layer is decreased by subjecting the AlN layer to the annealing treatment. Consequently, the AlN layer has tensile strain in a direction along the main surface of the SiC substrate at 27° C. According to such a configuration, by inheriting the low dislocation density of the AlN layer to the layers (the AlGaN layer and the GaN layer) above the AlN layer, the layers above the AlN layer can be grown in a state where the dislocation density is low at the growth temperature of the group III nitride crystals.

Further, in the configuration of the present disclosure, the AlGaN layer having a composition which is intermediate between the AlN layer and the GaN layer is interposed between the AlN layer and the GaN layer. As mentioned above, the AlGaN layer has a low dislocation density that inherits the dislocation density of the AlN layer, and contains Ga which weakens interatomic bonding force. Consequently, the GaN layer can be grown on the AlGaN layer in a nearly strain-free state at the growth temperature of the group III nitride crystals.

As a result, the GaN layer has tensile strain in a direction along the main surface of the SiC substrate at 27° C. The fact that the GaN layer has tensile strain at room temperature corresponds to the fact that the GaN layer has grown in a nearly strain-free state at the growth temperature of the GaN layer on the basis of the magnitude relationship of the linear expansion coefficients and the absolute values thereof mentioned above.

By growing the GaN layer in a nearly strain-free state as mentioned above, generation of a new dislocation due to crystal strain in the GaN layer having a low dislocation density inherited from the AlN layer via the AlGaN layer can be suppressed. As a result, according to the configuration of the present disclosure, the GaN layer having good crystallinity can be obtained.

The present disclosure below is based on the above findings found by the present inventors.

### Details of Embodiments of Present Disclosure

An embodiment of the present disclosure will be described hereinafter with reference to drawings. Note that the present disclosure is not limited to the illustrations below and is intended to be represented by the claims while also encompassing all modifications made within scopes and meanings that are equivalent to the claims.

### Embodiments of Present Disclosure

An embodiment of the present disclosure will be described hereinafter, with reference to the drawings.

### (1) Semiconductor Laminate

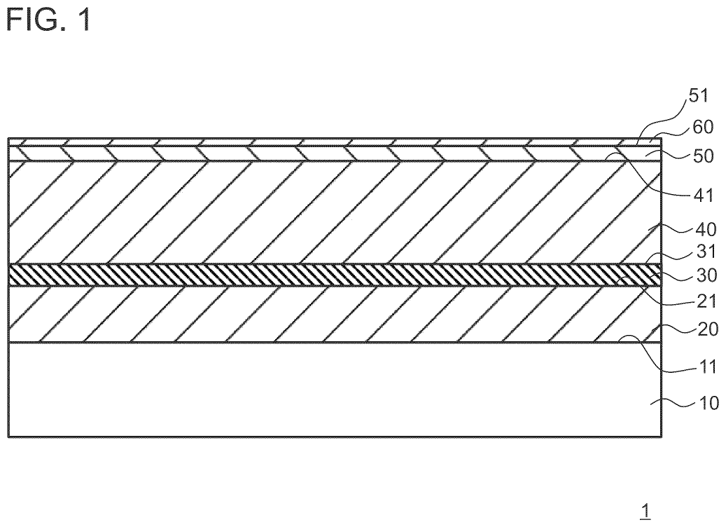

A semiconductor laminate (a group III nitride laminate substrate) 1 according to the present embodiment will be described with reference to FIG. 1.

Hereinafter, in a crystal of, for example, a group III nitride semiconductor having wurtzite structure, a <0001> axis is referred to as a “c-axis” and the (0001) plane is referred to as a “c-plane.” The (0001) plane may in some cases be referred to as the “+c-plane (group III element polar plane),” and the (000-1) plane may in some cases be referred to as the “−c-plane (nitrogen (N) polar plane).” In addition, a <1-100> axis (for example, the [1-100] axis) is referred to as an “m-axis,” and a {1-100} plane is referred to as an “m-plane.” In addition, an <11-20> axis (for example, the [11-20] axis) is referred to as an “a-axis,” and an {11-20} plane is referred to as an “a-plane.”

Hereinafter, a lattice constant in a state where no lattice strain is generated in a crystal (in a strain-free state) may in some cases be referred to as a “bulk lattice constant” or a “completely relaxed lattice constant.” The unit “arcsec,” which is the unit of a full width at half maximum FWHM in X-ray rocking curve measurement described later, means arcsecond.

As illustrated in FIG. 1, the semiconductor laminate 1 (hereinafter also referred to as the “laminate 1”) of the present embodiment includes, for example, a substrate 10, a base layer (first layer) 20, an intermediate layer (second layer, buffer layer) 30, an electron transport layer (third layer) 40, and an electron supply layer (fourth layer) 50. The laminate 1 may further include a cap layer (fifth layer) 60. However, as described later, the cap layer 60 may not be provided.

### Substrate

The substrate 10 comprises, for example, silicon carbide (SiC). The polytype of the SiC substrate as the substrate 10 is, for example, 4H, 6H, or 3C but is not limited thereto. Alternatively, the substrate 10 may be a composite substrate which is a substrate of a material other than SiC, such as Si or sapphire, with only the outermost surface having the polytype of 4H, 6H, or 3C.

Although the conductivity of the substrate 10 is not particularly limited, the substrate 10 has preferably semi-insulating properties.

The substrate 10 has a main surface (base surface) 11. In the present embodiment, the low-index crystal plane closest to the main surface 11 is, for example, the c-plane ((0001) plane, Si plane).

The c-axis of the substrate 10 may be inclined at a predetermined off-angle with respect to the normal line to the main surface 11. The magnitude of the off-angle in the main surface 11 is, for example, more than 0° and 1° or less and may be more than 0° and 0.1° or less. The off-angle in the main surface 11 may have distribution in the plane within the above mentioned range. The inclination direction (off-direction) of the off-angle in the main surface 11 may be, for example, the a-axis direction or the m-axis direction but is not limited thereto.

The diameter of the substrate 10 may be, for example, 2 inches (50.8 mm) or more, 4 inches (100 mm) or more, or 6 inches (150 mm) or more.

The thickness of the substrate 10 is not particularly limited, but depends on the diameter of the substrate 10. Specifically, the thickness of the substrate 10 having a diameter of 2 inches is, for example, 300 μm or more and 500 μm or less (typically, 430 μm), the thickness of the substrate 10 having a diameter of 4 inches is, for example, 400 μm or more and 1000 μm or less (typically, 500 μm), and the thickness of the substrate 10 having a diameter of 6 inches is, for example, 400 μm or more and 1500 μm or less (typically, 600 μm).

The root mean square roughness RMS of a 5 μm square region of the main surface 11 of the substrate 10 measured with an atomic force microscope (AFM) is, for example, 1 nm or less, or may be 0.5 nm or less.

### Base Layer

The base layer 20 is, for example, configured such that the crystal of the main surface 11 of the substrate 10, which has the polytype of, for example, 4H, 6H, or 3C, is converted into a group III nitride semiconductor having wurtzite structure and the polytype of 2H. Specifically, the base layer 20 is provided on the main surface 11 of the substrate 10, for example, and comprises an AlN crystal. The base layer 20 is formed, for example, by heteroepitaxially growing the AN crystal on the main surface 11 of the substrate 10.

The base layer 20 has a main surface 21. The low-index crystal plane closest to the main surface 21 of the base layer 20 is, for example, the c-plane ((0001) plane, Al plane).

The base layer 20 is provided, for example, continuously over the entire main surface 11 of the substrate 10. In other words, the base layer 20 is not separated into a plurality of islands, for example. Consequently, the entire main surface 21 of the base layer 20 can be converted into the 2H structure.

In the present embodiment, as described later, by performing an annealing step S30 after a base layer formation step S20, the dislocation density in the main surface 21 of the base layer 20 after the annealing step S30 is decreased to be smaller than the dislocation density in the main surface 21 of the base layer 20 immediately after the base layer formation step S20. Specifically, the dislocation density in the main surface 21 of the base layer 20 immediately after the base layer formation step S20 is in the order of 10¹⁰ cm⁻² or more; however, the dislocation density in the main surface 21 of the base layer 20 after the annealing step S30 is decreased to, for example, 1×10¹⁰ cm⁻² or less or 1×10⁹ cm⁻² or less. Consequently, the intermediate layer 30 comprising an AlGaN crystal and the electron transport layer 40 comprising a GaN crystal can be grown above the base layer 20 in a state where the dislocation density is low at the growth temperature of the group III nitride crystals. As a result of such an annealing step S30, the base layer 20 including an AlN crystal has tensile strain in a direction (for example, the a-axis direction) along the main surface 11 of the substrate 10 at 27° C., for example.

The amount of strain of the base layer 20 in the a-axis direction and the amount of strain of the base layer 20 in the c-axis direction depend on, for example, the respective lattice constants of the substrate 10 and the base layer 20, the respective linear expansion coefficients of the substrate 10 and the base layer 20, conditions in the annealing step S30, and the like.

The “amount of strain in the a-axis direction” herein means, for example, a ratio of the change of the a-axis length (lattice constant in the a-axis direction) of a crystal constituting a predetermined layer from the a-axis length of a strain-free bulk crystal. A positive value of the amount of strain indicates that the crystal has tensile strain, whereas a negative value of the amount of strain indicates that the crystal has compressive strain. The “amount of strain in the c-axis direction” is also defined in the same manner as the “amount of strain in the a-axis direction” except that the a-axis direction is replaced with the c-axis direction.

In the present embodiment, as mentioned above, since the base layer 20 has tensile strain in a direction along the main surface 11 at 27° C., the amount of strain of the base layer 20 in the a-axis direction has a positive value.

On the other hand, in the present embodiment, the base layer 20 has compressive strain in the direction perpendicular to the main surface 11 at 27° C., that is, the amount of strain of the base layer 20 in the c-axis direction has a negative value.

The amount of strain ε₁ (%) of the base layer 20 in the c-axis direction at 27° C. is determined by, for example, formula (1):

$${ε}_{1} = ( {c}_{1} - {c}_{A 1 N} ) / {c}_{A 1 N} \times 100 \qquad ( 1 )$$

where c₁ represents the c-axis length of the AlN crystal constituting the base layer 20 and is obtained by measuring the diffraction angle of the (0002) plane of the base layer 20 by X-ray diffraction measurement (2θ-ω scan); and CAIN represents the c-axis length of a strain-free bulk AlN crystal.

Specifically, although the amount of strain ε₁ (%) of the base layer 20 in the c-axis direction at 27° C. depends also on the linear expansion coefficient of the substrate 10, the amount of strain ε₁ (%) is typically −0.1% or more and less than −0.01%, for example.

In the present embodiment, the thickness of the base layer 20 is, for example, 200 nm or more and 800 nm or less, or may be 300 nm or more and 500 nm or less.

By setting the thickness of the base layer 20 to 200 nm or more, the base layer 20 can be grown while stably covering the main surface 11 of the substrate 10 by a hydride vapor phase epitaxy (HVPE) method. Further, the thickness of the base layer 20 can be stably controlled by the HVPE method.

By setting the thickness of the base layer 20 to 200 nm or more, diffusion of impurities from the substrate 10 toward the electron transport layer 40 via the base layer 20 can be suppressed. Specifically, when the substrate 10 is a SiC substrate, diffusion of Si from the substrate 10 toward the electron transport layer 40 can be suppressed. Consequently, buffer leakage can be suppressed without doping impurities such as Fe and C, which form a deep energy level, at a high concentration between the base layer 20 including an AlN crystal and the electron transport layer 40 including a GaN crystal.

On the other hand, by setting the thickness of the base layer 20 to 800 nm or less, a decrease in productivity can be suppressed.

By setting the thickness of the base layer 20 to 800 nm or less, warpage of the laminate 1 and cracking of the base layer 20 and the like due to a difference between the linear expansion coefficient of the base layer 20 and the linear expansion coefficients of other layers can be suppressed.

In the present embodiment, the base layer 20 is grown using an HVPE method enabling high-speed growth. A conventional MOVPE method requires several hours to grow the base layer 20 comprising an AlN crystal and having a thickness of 200 nm or more and 800 nm or less. On the other hand, in the present embodiment, the base layer 20 can be grown in several minutes by using an HVPE method.

In the present embodiment, incorporation of excessive carbon (C) into the base layer 20 can be suppressed by growing the base layer 20 by an HVPE method using no organic raw material. Specifically, the C concentration in the base layer 20 may be, for example, 1×10¹⁹ cm⁻³ or less, 1×10¹⁸ cm⁻³ or less, or 1×10¹⁷ cm⁻³ or less.

In the present embodiment, the crystallinity of the base layer 20 can be improved by growing the base layer 20 having a thickness within the above mentioned range by the HVPE method and then performing the annealing step S30 described later.

Here, when the full width at half maximum (FWHM) of diffraction from a predetermined crystal plane of AlN in X-ray rocking curve measurement is plotted with respect to the thickness of the base layer 20, the X-ray diffraction full width at half maximum of AlN shows a concave up tendency.

Specifically, for example, when the thickness of the base layer 20 is 200 nm or more and 800 nm or less, the full width at half maximum of the (0002) diffraction from the base layer 20 in X-ray rocking curve measurement is 200 arcseconds (arcsec) or less, and the full width at half maximum of the (10-12) diffraction from the base layer 20 in X-ray rocking curve measurement is 400 arcseconds or less.

For example, when the thickness of the base layer 20 is 300 nm or more and 500 nm or less, the full width at half maximum of the (0002) diffraction from the base layer 20 in X-ray rocking curve measurement is 180 arcseconds or less, and the full width at half maximum of the (10-12) diffraction from the base layer 20 measured in X-ray rocking curve measurement is 380 arcseconds or less.

By improving the crystallinity of the base layer 20 in this manner, the crystallinity of each layer grown above the base layer 20 can be improved.

### Intermediate Layer

The intermediate layer 30 is, for example, provided on the main surface 21 of the base layer 20 and comprises an AlGaN crystal. The intermediate layer 30 is, for example, formed by heteroepitaxially growing an AlGaN crystal on the main surface 21 of the base layer 20. That is, the intermediate layer 30 comprising an AlGaN crystal and having a composition which is intermediate between the base layer 20 and the electron transport layer 40 is interposed between the base layer 20 and the electron transport layer 40. As a result, lattice strain caused by lattice mismatch between the base layer 20 comprising an AlN crystal and the electron transport layer 40 comprising a GaN crystal can be further relaxed.

The intermediate layer 30 has a main surface 31. The low-index crystal plane closest to the main surface 31 of the intermediate layer 30 is, for example, the c-plane ((0001) plane, group III element polar plane).

In the present embodiment, for example, the intermediate layer 30 comprising an AlGaN crystal is coherently provided (coherently grown) on the main surface 21 of the base layer 20 having tensile strain. In other words, the intermediate layer 30 is pseudomorphic with respect to the base layer 20 having tensile strain, for example.

The term “coherently provided (coherently grown)” or the state of “pseudomorphic” as used herein refers to a state in which an upper layer grows so that the crystal axis of the upper layer is pseudo-aligned with the crystal axis of a lower layer. This state in the present embodiment means a state in which the a-axis length of the intermediate layer 30 comprising an AlGaN crystal coincides with the a-axis length of the base layer 20 comprising an AlN crystal in a reciprocal lattice map near the (11-24) diffraction of AlN obtained in X-ray diffraction measurement.

As mentioned above, by providing the intermediate layer 30 coherently on the base layer 20, the good crystallinity of the base layer 20 can be inherited to the intermediate layer 30. As a result, the crystallinity of the electron transport layer 40 comprising a GaN crystal can be improved via the intermediate layer 30.

In the present embodiment, since the intermediate layer 30 comprising an AlGaN crystal is coherently provided on the main surface 21 of the base layer 20 comprising an AlN crystal and having tensile strain, the intermediate layer 30 has tensile strain in a direction along the main surface 11 (for example, the a-axis direction) at 27° C., for example.

In the present embodiment, as mentioned above, since the intermediate layer 30 has tensile strain in a direction along the main surface 11 (for example, the a-axis direction) at 27° C., the amount of strain of the base layer 20 in the a-axis direction has a positive value.

On the other hand, in the present embodiment, the intermediate layer 30 has compressive strain in a direction perpendicular to the main surface 11 at 27° C. That is, the amount of strain of the intermediate layer 30 in the c-axis direction has a negative value.

The amount of strain ε₂ (%) of the intermediate layer 30 in the c-axis direction is determined by, for example, formula (2):

$${ε}_{2} = ( {c}_{2} - {c}_{A 1 GaN} ) / {c}_{A 1 GaN} \times 100 \qquad ( 2 )$$

where c₂ represents the c-axis length of the AlGaN crystal constituting the intermediate layer 30 and is obtained by measuring the diffraction angle of the (0002) plane of the intermediate layer 30 by X-ray diffraction measurement (2θ-ω scan); and c_{AlGaN} represents the c-axis length of a strain-free bulk AlGaN crystal.

Specifically, although the amount of strain ε₂ (%) of the intermediate layer 30 in the c-axis direction at 27° C. depends on the linear expansion coefficient of a SiC substrate as the substrate 10, the Al composition ratio x of the intermediate layer 30 comprising an AlGaN crystal, and the like, the amount of strain ε₂ (%) is typically −0.1% or more and less than −0.01%.

In the present embodiment, the intermediate layer 30 comprises a crystal represented by the composition formula of AlₓGa₁₋ₓN. The Al composition ratio x in the intermediate layer 30 is, for example, 0.75 or more and 0.96 or less.

By setting the Al composition ratio x in the intermediate layer 30 to 0.75 or more, overlap of the (0006) diffraction peak of SiC as the substrate 10 with the (0002) diffraction peak of AlGaN as the intermediate layer 30 in X-ray diffraction measurement can be suppressed. Consequently, the Al composition ratio in the intermediate layer 30 can be stably controlled.

By setting the Al composition ratio x in the intermediate layer 30 to 0.75 or more, the intermediate layer 30 can be stably coherently grown with respect to the base layer 20 comprising an AlN crystal and having tensile strain. Consequently, the good crystallinity of the base layer 20 can be stably inherited to the intermediate layer 30.

On the other hand, when the Al composition ratio x in the intermediate layer 30 exceeds 0.96, the electron transport layer 40 comprising a GaN crystal coherently grows with respect to the intermediate layer 30 comprising an AlGaN crystal at least in the initial stage of growth of the electron transport layer 40. Therefore, during the growth of the electron transport layer 40, the GaN crystal constituting the electron transport layer 40 may be distorted, and a new dislocation may be generated in the electron transport layer 40. As a result, the effect of improving the crystallinity of the electron transport layer 40 due to the interposition of the intermediate layer 30 comprising an AlGaN crystal may not be sufficiently obtained.

On the other hand, by setting the Al composition ratio x in the intermediate layer 30 to 0.96 or less, the electron transport layer 40 comprising a GaN crystal can be stably grown on the intermediate layer 30 comprising an AlGaN crystal in a nearly strain-free state at the growth temperature of the electron transport layer 40. Consequently, generation of a new dislocation during the growth of the electron transport layer 40 can be suppressed. As a result, the effect of improving the crystallinity of the electron transport layer 40 due to the interposition of the intermediate layer 30 comprising an AlGaN crystal can be stably obtained.

In the present embodiment, the thickness of the intermediate layer 30 is, for example, 30 nm or more and 600 nm or less. By setting the thickness of the intermediate layer 30 to 30 nm or more, the effect of relaxing the lattice strain of the electron transport layer 40 due to the intermediate layer 30 can be stably obtained. On the other hand, by setting the thickness of the intermediate layer 30 to 600 nm or less, the intermediate layer 30 can be stably coherently grown on the base layer 20.

In the present embodiment, the intermediate layer 30 may be doped with an impurity which is an element excluding Al, Ga, and N constituting the host material, for example. Examples of the impurity include oxygen (O), carbon (C), silicon (Si), and iron (Fe). Specifically, the total concentration of the impurities in the intermediate layer 30 may be, for example, less than 3×10¹⁹ cm⁻³. It has been confirmed from X-ray diffraction measurement that when the total concentration of the impurities in the intermediate layer 30 is within the above-mentioned range, the lattice constant of the intermediate layer 30 comprising an AlGaN crystal is equal to the lattice constant of an undoped AlGaN crystal coherently grown on an AlN crystal.

### Electron Transport Layer

The electron transport layer 40 is, for example, configured to generate two-dimensional electron gas (2DEG) in a region located closer to an electron supply layer 50 such that electrons can be transported when a semiconductor element 2 is driven, as described later. Specifically, the electron transport layer 40 is provided, for example, on the main surface 31 of the intermediate layer 30 and comprises a GaN crystal. The electron transport layer 40 is formed, for example, by heteroepitaxially growing a GaN crystal on the main surface 31 of the intermediate layer 30.

The electron transport layer 40 has, for example, a main surface 41. In the present embodiment, the low-index crystal plane closest to the main surface 41 of the electron transport layer 40 is, for example, the c-plane ((0001) plane, Ga plane).

In the present embodiment, since the electron transport layer 40 is epitaxially grown on the main surface 31 of the above mentioned intermediate layer 30, the electron transport layer 40 has tensile strain in a direction along the main surface 11 (for example, the a-axis direction) at 27° C., for example. Note that the electron transport layer 40 is not lattice-matched with the intermediate layer 30.

In the present embodiment, as mentioned above, since the electron transport layer 40 has tensile strain in a direction along the main surface 11 at 27° C., the amount of strain of the electron transport layer 40 in the a-axis direction has a positive value.

On the other hand, in the present embodiment, the electron transport layer 40 has compressive strain in a direction perpendicular to the main surface 11 at 27° C., that is, the amount of strain of the base layer 20 in the c-axis direction has a negative value.

The amount of strain ε₃ (%) of the electron transport layer 40 in the c-axis direction is, for example, determined by formula (3):

$${ε}_{3} = ( {c}_{3} - {c}_{GaN} ) / {c}_{GaN} \times 100 \qquad ( 3 )$$

where c₃ represents the c-axis length of the GaN crystal constituting the electron transport layer 40 and is obtained by measuring the diffraction angle of the (0002) plane of the electron transport layer 40 by X-ray diffraction measurement (2θ-ω scan); and c_{GaN} represents the c-axis length of a strain-free bulk GaN crystal.

Specifically, the amount of strain ε₃ (%) of the electron transport layer 40 in the c-axis direction at 27° C. may be, for example, −0.1% or more and less than −0.01%, or −0.06% or more and −0.02% or less.

As mentioned above, the fact that the amount of strain ε₃ of the electron transport layer 40 in the c-axis direction at room temperature is within the above mentioned range corresponds to the fact that the electron transport layer 40 grows in a nearly strain-free state at the growth temperature of the electron transport layer 40.

In this manner, by growing the electron transport layer 40 in a nearly strain-free state at the growth temperature of GaN, the electron transport layer 40 with high quality can be grown even when the thickness of the electron transport layer 40 is decreased.

In the present embodiment, the thickness of the electron transport layer 40 is, for example, 1 μm or less. In the present embodiment, by setting the thickness of the electron transport layer 40 to 1 μm or less, warpage of the laminate 1 due to a difference between the linear expansion coefficient of the electron transport layer 40 and the linear expansion coefficients of other layers can be suppressed. Consequently, lithography accuracy can be improved. In addition, in the present embodiment, by setting the thickness of the electron transport layer 40 to 1 μm or less, buffer leakage current due to slight conductivity of GaN itself constituting the electron transport layer 40 can be suppressed.

The lower limit of the thickness of the electron transport layer 40 is not limited. However, from the viewpoint of generating a predetermined two-dimensional electron gas (2DEG) in the electron transport layer 40, the thickness of the electron transport layer 40 may be, for example, 100 nm or more.

In the present embodiment, even when the thickness of the electron transport layer 40 is within the above mentioned range, the full width at half maximum of a diffraction peak of the electron transport layer 40 in X-ray rocking curve measurement is small. Specifically, the full width at half maximum of the (0002) diffraction from the electron transport layer 40 in X-ray rocking curve measurement may be, for example, 300 arcseconds or less, 270 arcseconds or less, or 250 arcseconds or less. The full width at half maximum of the (10-12) diffraction from the electron transport layer 40 in X-ray rocking curve measurement may be, for example, 410 arcseconds or less, 380 arcseconds or less, or 350 arcseconds or less.

In the present embodiment, the dislocation density of the electron transport layer 40 can be decreased by growing the electron transport layer 40 in a nearly strain-free state.

Here, when the electron transport layer 40 is three-dimensionally grown in a conventional method, the dislocation density can be decreased by associating dislocations during the three-dimensional growth. However, in this case, impurities such as O may be mixed through a facet other than the c-plane during the three-dimensional growth.

In a case where the electron transport layer 40 is grown in a step-flow manner without being three-dimensionally grown, the dislocation density decreases as the growth film thickness increases. However, in this case, the degree of decrease in the dislocation density is lower than that in the case of three-dimensional growth. Therefore, unless the electron transport layer 40 is grown to be very thick, the dislocation density cannot be sufficiently decreased.

In contrast, in the present embodiment, by growing the electron transport layer 40 in a nearly strain-free state on the intermediate layer 30 including an AlGaN crystal with a low dislocation density, the dislocation density of the electron transport layer 40 can be decreased without three-dimensionally growing the electron transport layer 40 and without growing the electron transport layer 40 to be thick.

Specifically, even when the thickness of the electron transport layer 40 is within the above mentioned range, the dislocation density in the main surface 41 of the electron transport layer 40 may be, for example, 1×10⁹ cm⁻² or less, 5×10⁸ cm⁻² or less, or 1×10⁸ cm⁻² or less. The dislocation density in the main surface 41 of the electron transport layer 40 can be measured by, for example, a multiphoton excitation microscope.

As mentioned above, gate leakage caused when the semiconductor element 2 is driven can be reduced by decreasing the dislocation density in the main surface 41 of the electron transport layer 40. Consequently, deterioration of a gate electrode caused when the semiconductor element 2 is driven can be suppressed.

As a result, reliability of the semiconductor element 2 as an HEMT can be improved.

The lower limit of the dislocation density in the main surface 41 of the electron transport layer 40 is considered to be, for example, 1×10⁷ cm⁻² because a method that does not cause three-dimensional growth is employed.

In the present embodiment, the electron transport layer 40 is grown (through step flow growth) with the c-plane as a growth surface without three-dimensionally growing the electron transport layer 40 by a production method described later, so that contamination of impurities such as O through a facet other than the c-plane is suppressed. Specifically, the O concentration in the electron transport layer 40 is, for example, 1×10¹⁶ cm⁻³ or less over the entire electron transport layer 40 excluding the region from the main surface 41 of the electron transport layer 40 up to a depth of 200 nm. In this manner, an increase in the free electron concentration in the electron transport layer 40 can be suppressed by suppressing contamination of O serving as an n-type impurity (donor) in the electron transport layer 40. Here, the reason for “excluding the region up to a depth of 200 nm” is as follows. Secondary ion mass spectrometry (SIMS), which is used for impurity analysis, is usually affected by contamination of a sample surface. Therefore, reliability of results of analysis in the region up to the depth of 200 nm is lowered. As a result, the measurement value of the impurity concentration in said region tends to be higher than the actual concentration. Therefore, in the present embodiment, it is assumed that the actual O concentration in the electron transport layer 40 is 1×10¹⁶ cm⁻³ or less up to the main surface 41 of the electron transport layer 40.

In the present embodiment, diffusion of Si from the substrate 10 toward the electron transport layer 40 is suppressed by setting the thickness of the base layer 20 to 200 nm or more. Specifically, the Si concentration in the electron transport layer 40 is, for example, 1×10¹⁶ cm⁻³ or less over the entire electron transport layer 40 excluding the region from the main surface 41 of the electron transport layer 40 up to a depth of 200 nm. In this manner, an increase in the free electron concentration in the electron transport layer 40 can be suppressed by suppressing contamination of Si serving as an n-type impurity (donor) in the electron transport layer 40. Here, the reason for “excluding the region up to a depth of 200 nm” is the same as the reason stipulated regarding the O concentration. Therefore, in the present embodiment, it is assumed that the actual Si concentration in the electron transport layer 40 is 1×10¹⁶ cm⁻³ or less up to the main surface 41 of the electron transport layer 40.

In this manner, an increase in buffer leakage current can be suppressed by suppressing an increase in the free electron concentration in the electron transport layer 40. A decrease in the On/Off current ratio can be suppressed by suppressing an increase in buffer leakage current when the 2DEG in the second layer is pinched off. Further, by suppressing an increase in buffer leakage current, leakage current between elements can be suppressed, and interference in operation between adjacent elements can be suppressed.

In the present embodiment, as mentioned above, by suppressing contamination of Si and O serving as n-type impurities in the electron transport layer 40, the electron transport layer 40 does not need to be doped with impurities such as Fe and C that form a deep energy level at a high concentration. Specifically, each of the Fe concentration and the C concentration in the electron transport layer 40 is, for example, 1×10¹⁶ cm⁻³ or less over the entire electron transport layer 40 excluding the region from the main surface 41 of the electron transport layer 40 up to a depth of 200 nm. Consequently, charging and discharging of impurities that form a deep energy level can be suppressed when the semiconductor element 2 is driven. That is, generation of hysteresis accompanying charging and discharging of impurities can be suppressed. As a result, the semiconductor element 2 can be stably operated. Here, the reason for “excluding the region up to a depth of 200 nm” is the same as the reason stipulated regarding the O concentration. Therefore, in the present embodiment, it is assumed that each of the actual Fe concentration and the actual C concentration in the electron transport layer 40 is 1×10¹⁶ cm⁻³ or less up to the main surface 41 of the electron transport layer 40.

In the present embodiment, the electron transport layer 40 is grown (through step flow growth) with the c-plane as a growth surface by a production method described later, so that the electron transport layer 40 has good surface flatness. Specifically, the root mean square roughness RMS of a 5 μm square region of the main surface 41 of the electron transport layer 40 measured with an atomic force microscope (AFM) may be, for example, 1 nm or less or 0.5 nm or less.

### Electron Supply Layer

The electron supply layer 50 is configured to generate 2DEG in the electron transport layer 40, for example. Specifically, the electron supply layer 50 comprises a group III nitride crystal, which has a band gap wider than that of GaN constituting the electron transport layer 40 and has a lattice constant smaller than the lattice constant of GaN constituting the electron transport layer 40. The group III nitride constituting the electron supply layer 50 is represented by the composition formula of AlₓIn_{y}Ga_{1-x-y}N (where 0<x≤1, 0≤y<1, and 0<x+y≤1), and examples thereof include AlN, AlGaN, InAlN, and AlInGaN. The group III nitride constituting the electron supply layer 50 may further include scandium (Sc) as a constituent element. The electron supply layer 50 is provided, for example, on the electron transport layer 40. The electron supply layer 50 is formed, for example, by heteroepitaxially growing a crystal of the above-mentioned group III nitride on the main surface 41 of the electron transport layer 40.

The electron supply layer 50 has a main surface 51. In the present embodiment, the low-index crystal plane closest to the main surface 51 of the electron supply layer 50 is, for example, the c-plane ((0001) plane, group III element polar plane).

The electron supply layer 50 is coherently provided (coherently grown) on the main surface 41 of the electron transport layer 40 including a GaN crystal, for example. In other words, the electron supply layer 50 is, for example, pseudomorphic with respect to the electron transport layer 40.

The thickness of the electron supply layer 50 is, for example, 5 nm or more and 50 nm or less, or may be 10 nm or more and 30 nm or less. Gate leakage current can be reduced by setting the thickness of the electron supply layer 50 to 5 nm or more or 10 nm or more. On the other hand, by setting the thickness of the electron supply layer 50 to 50 nm or less or 30 nm or less, the threshold voltage can be made a predetermined value or less, and switching characteristics can be improved.

In the present embodiment, the electron supply layer 50 has good surface flatness similarly to the electron transport layer 40. Specifically, the root mean square roughness RMS of a 5 μm square region of the main surface 51 of the electron supply layer 50 measured with an atomic force microscope (AFM) is, for example, equal to that of the electron transport layer 40.

### Cap Layer

The cap layer 60 is, for example, provided on the electron supply layer 50 and includes GaN. The cap layer 60 is formed, for example, by heteroepitaxially growing a GaN crystal on the main surface 51 of the electron supply layer 50. By forming the cap layer 60 on the main surface 51 of the electron supply layer 50 in this manner, when the electron supply layer 50 comprises an AlGaN crystal, Ga can be prevented from being selectively evaporated from an AlGaN surface at the time of decreasing temperature after growth, and formation of an Al-rich AlGaN layer can be suppressed, for example.

The thickness of the cap layer 60 is, for example, 1 nm or more and 10 nm or less, or may be 2 nm or more and 5 nm or less. By setting the thickness of the cap layer 60 to 1 nm or more or 2 nm or more, evaporation of the Ga component or the In component can be stably suppressed. On the other hand, by setting the thickness of the cap layer 60 to 10 nm or less or 5 nm or less, generation of a current component flowing in the cap layer 60 can be suppressed. Consequently, inhibition of device operation due to the cap layer 60 can be suppressed.

In the laminate 1 configured as mentioned above, warpage of the laminate 1 can be reduced by decreasing the thickness of the electron transport layer 40 as mentioned above. Specifically, warpage per 50.8 mm along the length of the laminate 1 is, for example, 20 μm or less, or may be 10 μm or less. Consequently, a decrease in lithography accuracy due to warpage of the laminate 1 can be suppressed. As a result, the production yield of the semiconductor element 2 can be improved.

Incidentally, the smaller the warpage of the laminate 1, the better, and the warpage is, for example, 0 μm or more.

### (2) Semiconductor Element

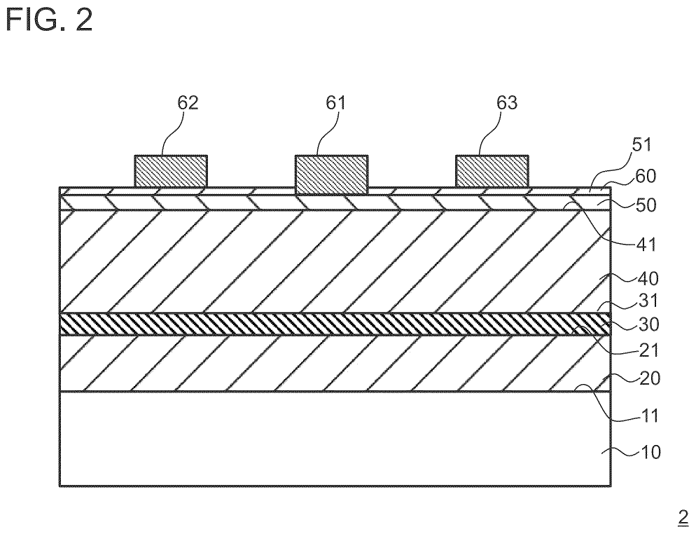

Next, a semiconductor element of the present embodiment will be described with reference to FIG. 2.

As illustrated in FIG. 2, the semiconductor element 2 of the present embodiment is, for example, produced using the above mentioned laminate 1, and is configured as an HEMT. Specifically, the semiconductor element 2 includes, for example, a substrate 10, a base layer 20, an intermediate layer 30, an electron transport layer 40, an electron supply layer 50, a cap layer 60, a gate electrode 61, a source electrode 62, and a drain electrode 63. That is, the semiconductor element 2 includes the above mentioned electron transport layer 40 comprising a GaN crystal as at least a part of an active layer.

### Electrode

The gate electrode 61 is provided above the electron supply layer 50. The gate electrode 61 may be in contact with the electron supply layer 50, or may be provided above the electron supply layer 50 via the cap layer 60, for example. The gate electrode 61 includes, for example, a multilayer structure (Ni/Au) of nickel (Ni) and gold (Au).

The source electrode 62 is, for example, provided above the electron supply layer 50 via the cap layer 60. The source electrode 62 is disposed at a position away from the gate electrode 61 by a predetermined distance. The source electrode 62 includes, for example, a multilayer structure (Ti/A) of titanium (Ti) and aluminum (Al).

The drain electrode 63 is, for example, provided above the electron supply layer 50 via the cap layer 60. The drain electrode 63 is disposed at a predetermined distance from the gate electrode 61, on the side opposite to the source electrode 62, with the gate electrode 61 positioned between the drain electrode 63 and the source electrode 62. The drain electrode 63 includes, for example, a multilayer structure of Ti and Al similarly to the source electrode 62. In the source electrode 62 and the drain electrode 63, a Ni/Au multilayer structure may be laminateed on the Ti/Al multilayer structure.

### (3) Semiconductor Laminate Production Method and Semiconductor Element Production Method

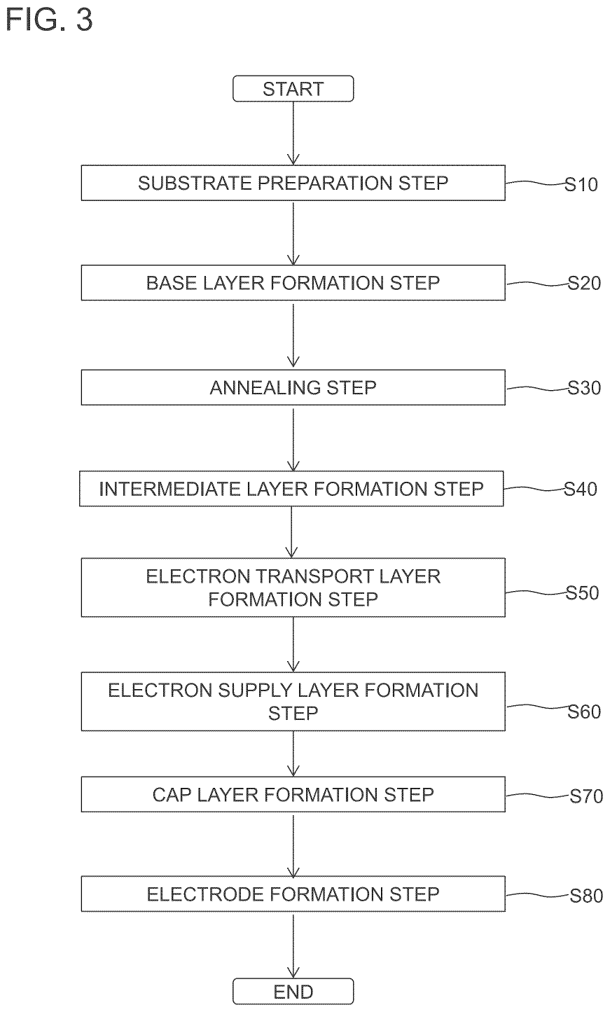

Next, a semiconductor laminate production method and a semiconductor element production method according to the present embodiment will be described with reference to FIGS. 1 to 3.

The semiconductor element production method according to the present embodiment includes, for example, a substrate preparation step S10, a base layer formation step S20, an annealing step S30, an intermediate layer formation step S40, an electron transport layer formation step S50, an electron supply layer formation step S60, a cap layer formation step S70, and an electrode formation step S80.

### S10: Substrate Preparation Step

First, a substrate 10 is prepared. For example, a semi-insulating SiC substrate of polytype 6H is prepared as the substrate 10.

### S20: Base Layer Formation Step

Then, a base layer 20 comprising an AlN crystal is heteroepitaxially grown on a main surface 11 of the substrate 10. The base layer 20 is grown by, for example, an HVPE method.

As a group III (Al) source gas, for example, aluminum monochloride (AlCl) gas or aluminum trichloride (AlCl₃) gas is used. AlCl gas or AlCl₃ gas can be generated by supplying hydrogen chloride (HCl) gas onto metal Al placed in an HVPE device. As a N source gas, for example, ammonia (NH₃) gas is used. These source gases may be mixed with a carrier gas including hydrogen (H₂) gas, nitrogen (N₂) gas, or a mixed gas thereof and supplied.

As crystal growth conditions, for example, at least one of the growth temperature, the V/III ratio, the growth rate, and the growth pressure is appropriately controlled. Consequently, the base layer 20 with high quality can be grown. Note that, the “V/III ratio” herein is a ratio of the supply amount (partial pressure) of the group V (N) source gas to the supply amount (partial pressure) of the group III (Al) source gas.

Specifically, the crystal growth conditions are set as follows, for example.
Growth temperature: 900° C. or higher and 1300° C. or lower
V/III ratio: 0.2 or more and 200 or less
Growth rate: 0.5 nm/minute or more and 3000 nm/minute or less
Growth pressure: 0.9 atm or more and 1.3 atm or less

At this time, by setting the growth pressure to 0.9 atm or more, that is, by growing the crystal under a pressure higher than that in a case of using a reduced-pressure growth device, the base layer 20 having good surface flatness can be easily grown. On the other hand, since high-pressure resistant growth devices require a pressure-resistant structure, the growth pressure may be set to 1.3 atm or less from the viewpoint of production cost.

At this time, in order to prevent AlN from adhering to a nozzle of a gas supply pipe for introducing various types of gas into a growth chamber of the HVPE device, HCl gas may be flowed. In this case, the ratio of the supply amount of HCl gas to the supply amount of AlCl gas or AlCl₃ gas is set to, for example, 0.1 or more and 100 or less.

By controlling the crystal growth conditions as mentioned above, the surface flatness of the base layer 20 can be improved.

Immediately after the base layer formation step S20, the base layer 20 has a high dislocation density of more than 10¹⁰ cm⁻². In the base layer formation step S20, since the lattice constant of bulk AlN is larger than the lattice constant of SiC, compressive strain is generated in the base layer 20 in a direction along the main surface 11 of the substrate 10 at the growth temperature of the base layer 20. However, since the linear expansion coefficient of AlN is larger than the linear expansion coefficient of SiC, the base layer 20 comprising an AlN crystal deforms in the pulling direction in the temperature decreasing process after the growth of the base layer 20. Therefore, the base layer 20 comprising an AlN crystal can be in any state of tensile strain, strain-free, and compressive strain at 27° C.

### S30: Annealing Step

After the base layer formation step S20 is completed, the base layer 20 is subjected to an annealing treatment.

For example, the annealing step S30 is continuously performed in the growth chamber of the same HVPE device without decreasing the temperature after the base layer formation step S20. Note that a heat treatment may be performed in another device in the annealing step S30 after the base layer formation step S20.

In the annealing step S30 of the present embodiment, by subjecting the base layer 20 to the annealing treatment, atoms in the base layer 20 move relatively freely, and the atomic arrangement changes. Consequently, atoms are rearranged so as to decrease dislocations in a high energy state. As a result, the dislocation density in the main surface 21 of the base layer 20 is decreased to be smaller than the dislocation density in the main surface 21 of the base layer 20 immediately after the base layer formation step S20. Specifically, the dislocation density in the main surface 21 of the base layer 20 is, for example, 1×10¹⁰ cm⁻² or less, or 1×10⁹ cm⁻² or less.

In this process, the base layer 20 undergoes lattice relaxation at the temperature of the annealing treatment from a state in which compressive strain is generated in the base layer 20 at the growth temperature of the base layer 20 in the base layer formation step S20. Consequently, after the annealing step S30, tensile strain is generated in the base layer 20 in a direction along the main surface 11 of the substrate 10 at 27° C.

At this time, in the present embodiment, for example, the base layer 20 is subjected to the annealing treatment in an atmosphere including nitrogen (N₂) gas.

In other words, the annealing treatment is performed in an atmosphere substantially free of H₂ gas, without supplying hydrogen (H₂) gas and NH₃ gas to the growth chamber. The phrase “substantially free of H₂ gas” herein means that the partial pressure in the growth chamber of each of H₂ gas and NH₃ gas that decomposes and releases H₂ gas is less than 1% based on the total pressure, for example. By performing the treatment in such an atmosphere, generation of point defects in the base layer 20 due to H₂ gas can be suppressed. Note that N₂ gas and an inert gas such as argon gas (Ar gas) may be mixed and supplied.

At this time, in the present embodiment, the temperature of the annealing treatment may be, for example, 1350° C. or higher and 1550° C. or lower, or 1390° C. or higher and 1490° C. or lower. By setting the temperature of the annealing treatment to 1350° C. or higher, or 1390° C. or higher, the above mentioned rearrangement of atoms is caused so as to decrease dislocations in a high energy state. In this process, the base layer 20 undergoes lattice relaxation at the temperature of the annealing treatment from a state in which compressive strain is generated in the base layer 20 at the growth temperature of the base layer 20 in the base layer formation step S20. On the other hand, decomposition of the substrate 10 comprising SiC can be suppressed by setting the temperature of the annealing treatment to 1550° C. or lower, or 1490° C. or lower.

At this time, in the present embodiment, the time of the annealing treatment is set to, for example, 10 minutes or longer and 300 minutes or shorter. By setting the time of the annealing treatment to 10 minutes or longer, the base layer 20 can sufficiently undergo lattice relaxation. On the other hand, by setting the time of the annealing treatment to 300 minutes or shorter, a decrease in the flatness of the main surface 21 of the base layer 20 can be suppressed.

By subjecting the base layer 20 to the annealing treatment under the above mentioned conditions, the atoms in the base layer 20 move freely, and the base layer 20 thus undergoes lattice relaxation at the temperature of the annealing treatment. Consequently, at the time of decreasing temperature after the annealing step S30, tensile strain is generated in the base layer 20 in a direction along the main surface 11 of the substrate 10 at 27° C. due to the difference between the linear expansion coefficient of the substrate 10 and the linear expansion coefficient of the base layer 20.

Further, the crystallinity of the base layer 20 can be improved by subjecting the base layer 20 to the annealing treatment under the above mentioned conditions.

Specifically, for example, when the thickness of the base layer 20 is set to 200 nm or more and 800 nm or less, the full width at half maximum of the (0002) diffraction from the base layer 20 in X-ray rocking curve measurement can be made 200 arcseconds or less, and the full width at half maximum of the (10-12) diffraction from the base layer 20 in X-ray rocking curve measurement can be made 400 arcseconds or less.

For example, when the thickness of the base layer 20 is set to 300 nm or more and 500 nm or less, the full width at half maximum of the (0002) diffraction from the base layer 20 in X-ray rocking curve measurement can be made 180 arcseconds or less, and the full width at half maximum of the (10-12) diffraction from the base layer 20 in X-ray rocking curve measurement can be made 380 arcseconds or less.

### S40: Intermediate Layer Formation Step

After the annealing step S30 is completed, an intermediate layer 30 comprising an AlGaN crystal is heteroepitaxially grown on a main surface 21 of the base layer 20 having been subjected to the annealing treatment. The intermediate layer 30 is grown by, for example, a metalorganic vapor phase epitaxy (MOVPE) method.

As a group III source gas, for example, trimethylaluminum (Al(CH₃)₃, TMA) gas and trimethylgallium (Ga(CH₃)₃, TMG) gas are used. As a N source gas, for example, NH₃ gas is used. These source gases may be mixed with a carrier gas including H₂ gas, N₂ gas, or a mixed gas thereof and supplied.

At this time, in the present embodiment, the growth temperature of the intermediate layer 30 is set to be lower than the temperature in the annealing step S30. Specifically, the growth temperature of the intermediate layer 30 is set to, for example, 900° C. or higher and 1200° C. or lower.

At this time, in the present embodiment, the intermediate layer 30 is coherently grown on the main surface 21 of the base layer 20, for example.

Here, as mentioned above, the intermediate layer formation step S40 is carried out at a growth temperature lower than the temperature in the annealing step S30. Therefore, the base layer 20, which has become strain-free in the annealing step S30, has tensile strain at the growth temperature of the intermediate layer formation step S40 due to the difference between the linear expansion coefficient of the substrate 10 and the linear expansion coefficient of the base layer 20. The intermediate layer 30 is coherently grown on the base layer 20 in which tensile strain has been generated as mentioned above.

As crystal growth conditions, for example, at least one of the V/III ratio, the growth rate, and the growth pressure is appropriately controlled together with the above mentioned growth temperature. Consequently, the intermediate layer 30 can be coherently grown on the base layer 20.

Specifically, the other crystal growth conditions are set as follows, for example.
V/III ratio: 1 or more and 10000 or less
Growth rate: 0.1 nm/minute or more and 100 nm/minute or less
Growth pressure: 0.01 atm or more and 1 atm or less

At this time, in the present embodiment, the Al composition ratio x in the intermediate layer 30 is set to, for example, 0.75 or more and 0.96 or less.

At this time, in the present embodiment, the thickness of the intermediate layer 30 is set to, for example, 30 nm or more and 600 nm or less.

### S50: Electron Transport Layer Formation Step

After the intermediate layer formation step S40 is completed, an electron transport layer 40 comprising a GaN crystal is heteroepitaxially grown on a main surface 31 of the intermediate layer 30. The electron transport layer 40 is grown by, for example, an MOVPE method, and the growth of the electron transport layer 40 is continuously performed in the same growth chamber of the MOVPE device as the intermediate layer formation step S40.

At this time, TMG gas is used as a Ga source gas. The other gases used in the electron transport layer formation step S50 are equivalent to those in the intermediate layer formation step S40.

In the present embodiment, by interposing the intermediate layer 30 comprising an AlGaN crystal between the base layer 20 and the electron transport layer 40, generation of compressive strain in the electron transport layer 40 comprising GaN can be suppressed, and the electron transport layer 40 can be grown in a nearly strain-free state.

Further, in the present embodiment, the electron transport layer 40 is grown in a step-flow manner (grown two-dimensionally) without three-dimensionally growing the electron transport layer 40. That is, the electron transport layer 40 is grown with the c-plane as a growth surface without generating facets other than the c-plane in the electron transport layer 40.

As crystal growth conditions, for example, at least one of the growth temperature, the growth rate, and the growth pressure is appropriately controlled.

Specifically, the crystal growth conditions are set as follows, for example.
Growth temperature: 900° C. or higher and 1200° C. or lower
V/III ratio: 1 or more and 30000 or less
Growth rate: 0.1 nm/minute or more and 10 nm/minute or less
Growth pressure: 0.01 atm or more and 1 atm or less

By growing the crystal as mentioned above, the electron transport layer 40 having high crystallinity can be formed while decreasing the thickness of the electron transport layer 40.

Specifically, the electron transport layer 40 can be formed such that the full width at half maximum of the (0002) diffraction from the electron transport layer 40 in X-ray rocking curve measurement is 300 arcseconds or less and the full width at half maximum of the (10-12) diffraction from the electron transport layer 40 in X-ray rocking curve measurement is 410 arcseconds or less, while making the thickness of the electron transport layer 40 1 μm or less, for example.

In the present embodiment, the dislocation density in a main surface 41 of the electron transport layer 40 can be made 1×10⁹ cm⁻² or less or 5×10⁸ cm⁻² or less by growing the electron transport layer 40 in a nearly strain-free state.

In the present embodiment, by growing the crystal as mentioned above, the impurity concentration in the electron transport layer 40 can be decreased as follows:
the O concentration in the electron transport layer 40 is 1×10¹⁶ cm⁻³ or less;
the Si concentration in the electron transport layer 40 is 1×10¹⁶ cm⁻³ or less; and
each of the Fe concentration and the C concentration in the electron transport layer 40 is 1×10¹⁶ cm⁻³ or less.

### S60: Electron Supply Layer Formation Step

Next, an electron supply layer 50 comprising a group III nitride crystal having a band gap wider than that of GaN constituting the electron transport layer 40 is heteroepitaxially grown on the main surface 41 of the electron transport layer 40. The electron supply layer 50 is grown by, for example, an MOVPE method, and the growth of the electron supply layer 50 is continuously performed in the same growth chamber of the MOVPE device as the electron transport layer formation step S50.

In the present embodiment, for example, the electron supply layer 50 including a crystal of AlN, AlGaN, InAlN, or AlInGaN is grown.

At this time, as an Al source gas, for example, TMA gas is used. As an In source gas, for example, trimethylindium (In(CH₃)₃, TMI) gas is used. The other gases used in the electron supply layer formation step S60 are similar to those in the electron transport layer formation step S50.

At this time, in the present embodiment, the electron supply layer 50 is coherently grown on the main surface 41 of the electron transport layer 40, for example.

As crystal growth conditions, for example, at least one of the growth temperature, the V/III ratio, the growth rate, and the growth pressure is appropriately controlled.

Specifically, the crystal growth conditions are set as follows, for example.
Growth temperature: 900° C. or higher and 1200° C. or lower
V/III ratio: 1 or more and 10000 or less
Growth rate: 0.1 nm/minute or more and 10 nm/minute or less
Growth pressure: 0.01 atm or more and 1 atm or less

At this time, in the present embodiment, the thickness of the electron supply layer 50 is set to, for example, 5 nm or more and 50 nm or less.

### S70: Cap Layer Formation Step

Thereafter, a cap layer 60 comprising GaN is grown on a main surface 51 of the electron supply layer 50. The cap layer 60 is grown by, for example, an MOVPE method, and the growth of the cap layer 60 is continuously performed in the same growth chamber of the MOVPE device as the electron supply layer formation step S60.

At this time, the thickness of the cap layer 60 is set to, for example, 1 nm or more and 10 nm or less.

The laminate 1 of the present embodiment is produced as mentioned above.

### S80: Electrode Formation Step

After the laminate 1 is produced, a gate electrode 61, a source electrode 62, and a drain electrode 63 are formed above the electron supply layer 50.

The semiconductor element 2 of the present embodiment is produced as mentioned above.

### (4) Summary of Present Embodiment

According to the present embodiment, one or more effects shown below are obtained.

(a) In the present embodiment, by subjecting, to the annealing treatment, the base layer 20 comprising an AlN crystal on the substrate 10 comprising SiC, the dislocation density in the main surface 21 of the base layer 20 can be decreased by the above mentioned rearrangement of atoms.

In this process, the base layer 20 undergoes lattice relaxation at the temperature of the annealing treatment from a state in which compressive strain is generated in the base layer 20 at the growth temperature of the base layer 20 in the base layer formation step S20. Consequently, after the annealing step S30, tensile strain is generated in the base layer 20 in a direction along the main surface 11 of the substrate 10 at 27° C. due to the difference between the linear expansion coefficient of the substrate 10 and the linear expansion coefficient of the base layer 20.

According to such a configuration, by inheriting the low dislocation density of the base layer 20 to the layers (the intermediate layer 30 and the electron transport layer 40) above the base layer 20 comprising an AlN crystal, the layers above the base layer 20 can be grown in a state where the dislocation density is low at the growth temperature of the group III nitride crystal.

(b) Further, in the present embodiment, the intermediate layer 30 comprising an AlGaN crystal and having a composition which is intermediate between the base layer 20 comprising an AlN crystal and the electron transport layer 40 comprising a GaN crystal is interposed between the base layer 20 and the electron transport layer 40. The intermediate layer 30 has a low dislocation density inheriting the dislocation density of the base layer 20 as mentioned above, and includes Ga which weakens interatomic bonding force. Consequently, the electron transport layer 40 comprising a GaN crystal can be grown in a nearly strain-free state on the intermediate layer 30 comprising an AlGaN crystal at the growth temperature of the group III nitride crystal.

Here, a mechanism through which the electron transport layer 40 comprising a GaN crystal grows in a nearly strain-free state due to the interposition of the intermediate layer 30 comprising an AlGaN crystal with a low dislocation density is not clear at present. However, the following mechanism is conceivable, for example.

The interatomic bond in AlN is stronger than that in GaN. Therefore, an atomic plane between an AlN layer and a GaN layer is unlikely to slip. Accordingly, a GaN layer coherently grows on an AlN layer.

In contrast, an AlGaN layer includes GaN which weakens interatomic bonding force. Consequently, an atomic plane slip between an AlGaN layer and a GaN layer easily occurs. It is considered that when a GaN layer is grown on an AlGaN layer, such an atomic plane slip phenomenon releases crystal strain in the GaN layer.

Furthermore, it has also been confirmed in another study that when a base layer including an AlN crystal has a high dislocation density (for example, in the order of 10¹⁰ cm⁻² or more), a GaN layer grown on an AlGaN layer is not strain-free (for example, when the Al composition ratio x of the AlGaN layer falls within the range of 0.5 to 1). This is probably because, when the number of dislocations is large, the dislocations prevent slippage at the interface between the GaN layer and the AlGaN layer.

Conversely, in the present embodiment, it is considered that the phenomenon in which the electron transport layer 40 comprising a GaN crystal grows in a nearly strain-free state on the intermediate layer comprising an AlGaN crystal with a low dislocation density is a phenomenon peculiar to the case where the base layer 20 comprising an AlN crystal with a low dislocation density exists.

In the present embodiment, by growing the electron transport layer 40 comprising a GaN crystal in a nearly strain-free state on the intermediate layer 30 comprising an AlGaN crystal in the above mentioned mechanism, the electron transport layer 40 comprising a GaN crystal has tensile strain in a direction along the main surface 11 of the substrate 10 at 27° C. on the basis of the magnitude relationship of the linear expansion coefficients and the absolute values thereof mentioned above.

By growing the electron transport layer 40 comprising a GaN crystal in a nearly strain-free state as mentioned above, generation of a new dislocation due to crystal strain can be suppressed in the electron transport layer 40 having a low dislocation density inherited from the base layer 20 via the intermediate layer 30. As a result, the electron transport layer 40 having good crystallinity can be obtained.

As mentioned above, according to the present embodiment, the semiconductor laminate 1 having high quality and the semiconductor element 2 having high quality can be obtained.

(c) In the present embodiment, by growing the electron transport layer 40 in a nearly strain-free state at the growth temperature of GaN, the crystallinity of the electron transport layer 40 can be improved even when the thickness of the electron transport layer 40 is decreased. Specifically, the thickness of the electron transport layer 40 is 1 μm or less, the full width at half maximum of the (0002) diffraction from the electron transport layer 40 in X-ray rocking curve measurement is 300 arcseconds or less, and the full width at half maximum of the (10-12) diffraction from the electron transport layer 40 in X-ray rocking curve measurement is 410 arcseconds or less. By improving the crystallinity of the electron transport layer 40 in this manner, mobility of the electron transport layer 40 can be improved, deterioration of the gate electrode can be suppressed, and reliability of the element can be improved.

### OTHER EMBODIMENTS

Hereinbefore, embodiments of the present disclosure have been specifically described. However, the present disclosure is not limited to the above-mentioned embodiments, and various modifications can be made without departing from the spirit of the present disclosure.

In the above mentioned embodiments, the case where the intermediate layer 30 comprises an AlGaN crystal has been described, but the present disclosure is not limited to this case. The intermediate layer 30 may comprise, for example, a crystal of either aluminum indium nitride (AlInN) or aluminum indium gallium nitride (AlInGaN). InN crystals are also known as crystals having bonding strength weaker than AlN crystals. Therefore, even in the case where the intermediate layer 30 comprises an AlInN crystal or an AlInGaN crystal, the strain relaxation effect due to the atomic plane slip phenomenon can be obtained similarly to the case where the intermediate layer 30 comprises an AlGaN crystal.

In the above mentioned embodiments, the case where the cap layer 60 is provided has been described. However, the cap layer 60 may not be provided.

The above mentioned embodiments are illustrated such that there is nothing provided in the region of the top surface of the cap layer 60 except for the electrodes. However, a protective film may be provided so as to cover the region of the top surface of the cap layer 60 except for the electrodes. Examples of the protective film include silicon nitride (SiN).

In the above mentioned embodiments, the case where the semiconductor element 2 is configured as a so-called metal-semiconductor (MES) gate type in which the gate electrode 61 is in direct contact with a semiconductor layer such as the electron supply layer 50 has been described. However, the semiconductor element 2 may be configured as a so-called metal-insulator-semiconductor (MIS) gate type in which an insulating layer including silicon oxide (SiO₂), aluminum oxide (Al₂O₃), or the like is inserted between the gate electrode 61 and a semiconductor layer such as the electron supply layer 50.

In the above mentioned embodiments, the case where the base layer 20 is grown by the HVPE method has been described. However, the base layer 20 may be grown by an MOVPE method.

In the above mentioned embodiments, the case where the intermediate layer 30 and the electron transport layer 40 are grown by the MOVPE method has been described. However, at least one of the intermediate layer 30 and the electron transport layer 40 may be grown by an HVPE method.

### EXAMPLES

Explanation will be given for various experimental results supporting an effect of the present disclosure hereinafter.

### (1) Experiment 1

### (1-1) Production of Semiconductor Laminate

Multiple laminates were produced under the following conditions, each laminate having an intermediate layer comprising an AlGaN with a different Al composition ratio.

### Conditions for Producing Laminates

### Substrate

Material: SiC (semi-insulating)
Diameter: 4 inches
Thickness: 400 μm
Low-index crystal plane closest to main surface: c-plane (without pattern processing on main surface)
Polytype: 6H

### Base Layer

Material: AlN
Growth method: HVPE method
Growth temperature: 1020° C.
Growth pressure: 0.987 atm (100 kPa)
V/III ratio: 50
Growth rate: 100 nm/minute
Thickness: 400 nm

### Annealing Step

Atmosphere: N₂ gas
Annealing treatment temperature: 1400° C.
Annealing treatment time: 60 minutes
   Intermediate layer
Material: AlGaN (or AlN)
Growth method: MOVPE method
Growth temperature: 1020° C.
Growth pressure: 0.1 atm
V/III ratio: 10
Growth rate: 5 nm/minute
Thickness: 80 nm

Note that the intermediate layer was produced without intentional impurity doping.

Al composition ratio: varying within the range of 65% or more and 100% or less

### Electron Transport Layer

Material: GaN
Growth method: MOVPE method
Growth conditions: following conditions allowing GaN crystal to grow in step-flow manner
Growth temperature: 1120° C.
Growth pressure: 0.4 atm
TMG flow rate: 50 sccm
V/III ratio: 5000
Growth rate: 20 nm/minute

Note that the electron transport layer was produced without intentional impurity doping.

Thickness: 400 nm

### (1-2) Evaluation

### X-Ray Diffraction Measurement: 2θ-ω Scan

In each of the laminates of Experiment 1 mentioned above, X-ray diffraction measurement (2θ-ω scan) was performed. As a result, the strain of the base layer was confirmed on the basis of the angle of the (0002) diffraction peak of AlN constituting the base layer. The Al composition ratio in the intermediate layer was determined on the basis of the angle of the diffraction peak of Al(Ga)N constituting the intermediate layer. Further, the angle 2θ of the (0002) diffraction peak of GaN constituting the electron transport layer was determined.

### X-Ray Rocking Curve Measurement

In each of the laminates of Experiment 1 mentioned above, X-ray rocking curve measurement of the (0002) diffraction from GaN constituting the electron transport layer and X-ray rocking curve measurement of the (10-12) diffraction from GaN constituting the electron transport layer were performed. As a result, the full width at half maximum (FWHM) of the (0002) diffraction from GaN and the full width at half maximum of the (10-12) diffraction from GaN were determined.

### (1-3) Results

### Strain of Base Layer

As a result of 2θ-ω scanning as the X-ray diffraction measurement, the angle of the (0002) diffraction peak of AlN constituting the base layer was smaller than the angle of the (0002) diffraction peak of AlN (bulk AlN) which was completely relaxed in all laminates. This result means that the c-axis length of the base layer decreases, that is, the a-axis length of the base layer increases at room temperature. From this result, it was confirmed that the base layer comprising an AlN crystal had tensile strain in a direction along the main surface of the substrate at room temperature.

### Dependence of Strain of Electron Transport Layer on Al Composition Ratio in Intermediate Layer

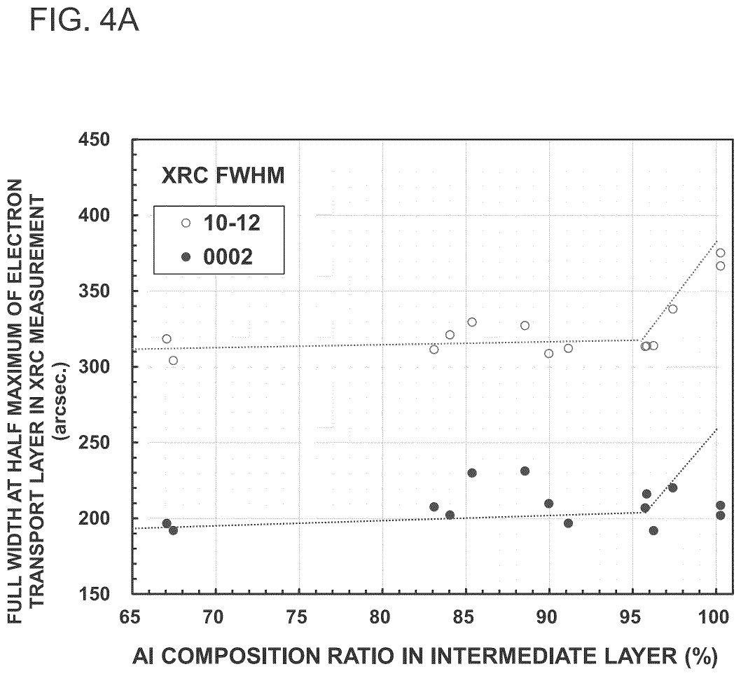

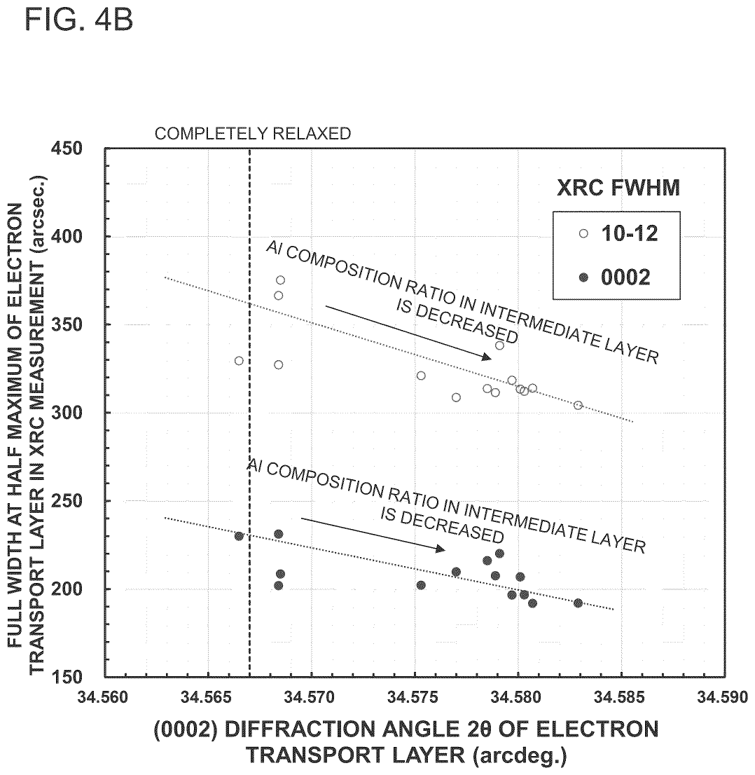

As shown in FIG. 4B, when the Al composition ratio in the intermediate layer was 100%, the angle 2θ of the (0002) diffraction peak of GaN constituting the electron transport layer was slightly smaller than the angle (34.567°) of the (0002) diffraction peak of completely relaxed GaN (bulk GaN). This result means that the c-axis length of the electron transport layer increases, that is, the a-axis length of the electron transport layer decreases. From this result, it was confirmed that when the intermediate layer was AlN, the electron transport layer had compressive strain in a direction along the main surface of the substrate at room temperature. Considering the fact that the linear expansion coefficients of GaN and AlN are larger than the linear expansion coefficient of SiC constituting the substrate, it is considered that the electron transport layer including a GaN crystal has been subjected to great compressive strain at the growth temperature of the electron transport layer, in this case. Considering the fact that the lattice constant of AlN is smaller than the lattice constant of GaN, it is considered that the electron transport layer comprising a GaN crystal has coherently grown on the intermediate layer comprising an AlN crystal at least in the early stage of growth, and the electron transport layer has thus undergone compressive strain at the growth temperature of the electron transport layer.

In contrast, when the Al composition ratio in the intermediate layer was decreased to less than 100%, particularly 96% or less, the angle 2θ of the (0002) diffraction peak of GaN constituting the electron transport layer was larger than the angle of the (0002) diffraction peak of completely relaxed GaN. This result means that the c-axis length of the electron transport layer decreases, that is, the a-axis length of the electron transport layer increases. From this result, it was confirmed that the electron transport layer had tensile strain in a direction along the main surface of the substrate at room temperature due to the interposition of the intermediate layer comprising an AlGaN crystal.

As the Al composition ratio in the intermediate layer decreased, the angle 2θ of the (0002) diffraction peak of GaN constituting the electron transport layer gradually increased. This result means that the c-axis length of the electron transport layer gradually decreases as the Al composition ratio in the intermediate layer decreases, that is, the a-axis length of the electron transport layer gradually increases. From this result, it was confirmed that the absolute value of the strain amount as the tensile strain of the electron transport layer increased as the Al composition ratio in the intermediate layer decreased.

### Dependence of Crystallinity of Electron Transport Layer on Al Composition Ratio in Intermediate Layer

As shown in FIG. 4A, when the Al composition ratio in the intermediate layer was 100%, the full width at half maximum of the (0002) diffraction from GaN constituting the electron transport layer was more than 270 arcseconds, and the full width at half maximum of the (10-12) diffraction therefrom was more than 410 arcseconds. From this result, it is considered that when the Al composition ratio in the intermediate layer was set to 100%, that is, when the intermediate layer comprising an AlGaN crystal was not provided, compressive strain generated in the electron transport layer at the growth temperature of the electron transport layer, and the crystallinity of the electron transport layer decreased (the dislocation density increased).

In contrast, when the Al composition ratio in the intermediate layer was less than 100%, the full width at half maximum of the (0002) diffraction from GaN constituting the electron transport layer was 270 arcseconds or less, and the full width at half maximum of the (10-12) diffraction therefrom was 410 arcseconds or less. From this result, it was confirmed that the electron transport layer could be grown in a nearly strain-free state at the growth temperature of the electron transport layer due to the interposition of the intermediate layer comprising an AlGaN crystal, and the crystallinity of the electron transport layer could be improved.

As the Al composition ratio in the intermediate layer decreased in the range of 96% or less, the full width at half maximum of each diffraction from the electron transport layer gradually decreased. From this result, it was confirmed that as the Al composition ratio in the intermediate layer decreased, the lattice strain of the electron transport layer could be further relaxed at the growth temperature of the electron transport layer, and the crystallinity of the electron transport layer could be stably improved.

### (2) Experiment 2

### (2-1) Production of Semiconductor Laminate

Multiple laminates were produced under equivalent conditions to Experiment 1 except that the thickness of the electron transport layer was changed within the range of 100 nm or more and 1 μm or less. In Experiment 2, the Al composition ratio in the intermediate layer was set to 84%.

### (2-2) Evaluation

### X-Ray Rocking Curve Measurement

In each of the laminates of Experiment 2 mentioned above, X-ray rocking curve measurement of the (0002) diffraction from GaN constituting the electron transport layer and X-ray rocking curve measurement of the (10-12) diffraction from GaN constituting the electron transport layer were performed. As a result, the full width at half maximum (FWHM) of the (0002) diffraction from GaN and the full width at half maximum of the (10-12) diffraction from GaN were determined.

Observation with Multiphoton Excitation Microscope

With respect to each of the laminates of Experiment 2 mentioned above, the main surface of the electron supply layer was observed using a multiphoton excitation microscope. As a result, the dislocation density in the main surface of the electron supply layer was determined.

### (2-3) Results

### Dependence of Crystallinity of Electron Transport Layer on Thickness of Electron Transport Layer

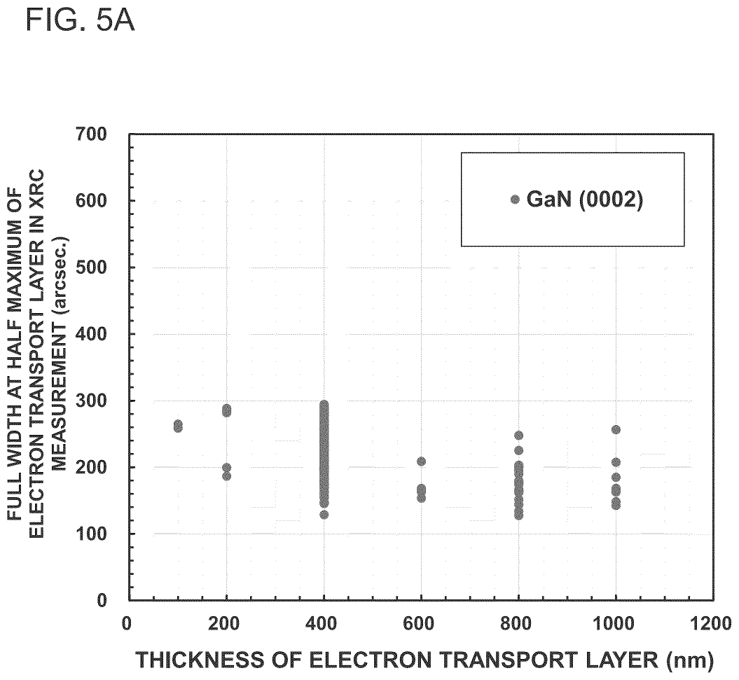

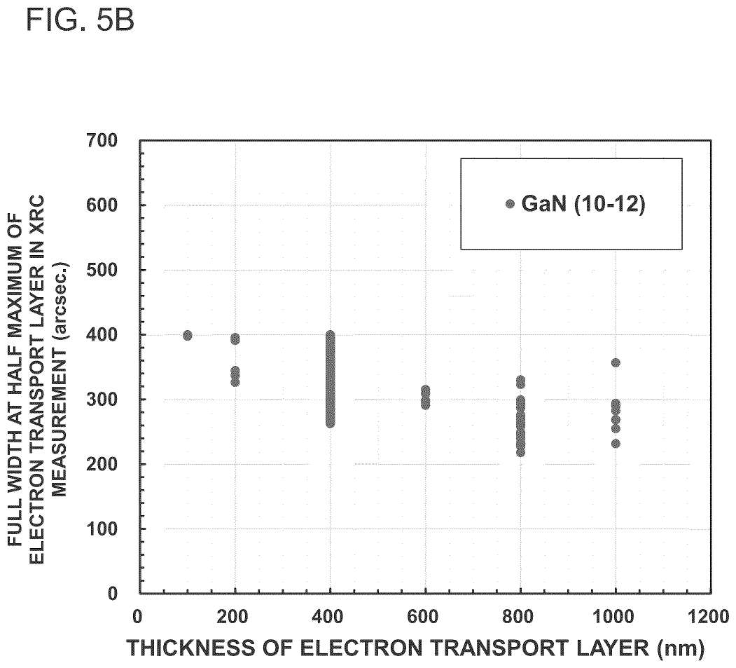

As shown in FIG. 5A and FIG. 5B, the full width at half maximum of the (0002) diffraction from GaN constituting the electron transport layer was 300 arcseconds or less, and the full width at half maximum of the (10-12) diffraction therefrom was 410 arcseconds or less within the range in which the thickness of the electron transport layer was set to 100 nm or more and 1 μm or less. From this result, it was confirmed that even when the thickness of the electron transport layer was set to 1 μm or less, the crystallinity of the electron transport layer could be improved by growing the electron transport layer in a nearly strain-free state.

### Dislocation Density

As a result of observation with a multiphoton excitation microscope, the dislocation density in the main surface of the electron supply layer was 5×10⁸ cm⁻² or less in each of the laminates in which the thickness of the electron transport layer was set to 100 nm or more and 1 μm or less. From this result, it was confirmed that by growing the electron transport layer in a nearly strain-free state, the dislocation density of the electron transport layer could be decreased without three-dimensionally growing the electron transport layer and without growing the electron transport layer to be thick.

### Preferable Aspects of the Present Disclosure

Preferable aspects of the present disclosure will be supplementarily described hereinafter.

### Supplementary Description 1

A semiconductor laminate, including:
a substrate including silicon carbide and having a main surface,
a first layer provided on the main surface of the substrate, the first layer including an aluminum nitride crystal,
a second layer provided on the first layer, the second layer including a crystal of any of aluminum gallium nitride, aluminum indium nitride, and aluminum indium gallium nitride, and
a third layer provided on the second layer, the third layer including a gallium nitride crystal;
in which the first layer has tensile strain in a direction along the main surface at 27° C.

### Supplementary Description 2

The semiconductor laminate according to supplementary description 1,
in which the third layer has tensile strain in a direction along the main surface at 27° C.

### Supplementary Description 3

The semiconductor laminate according to supplementary description 1 or 2,
in which the third layer has a thickness of 1 μm or less,
the full width at half maximum of the (0002) diffraction from the third layer in X-ray rocking curve measurement is 300 arcseconds or less, and
the full width at half maximum of the (10-12) diffraction from the third layer in X-ray rocking curve measurement is 410 arcseconds or less.

### Supplementary Description 4

The semiconductor laminate according to any one of supplementary descriptions 1 to 3,
in which the dislocation density in a main surface of the third layer is 1×10⁹ cm⁻² or less.

### Supplementary Description 5

The semiconductor laminate according to any one of supplementary descriptions 1 to 4,
in which the first layer has a thickness of 200 nm or more and 800 nm or less.

### Supplementary Description 6

The semiconductor laminate according to any one of supplementary descriptions 1 to 5,
in which the second layer is coherently provided on the first layer.

### Supplementary Description 7

The semiconductor laminate according to any one of supplementary descriptions 1 to 6,
in which the second layer includes a crystal represented by the composition formula of AlₓGa₁₋ₓN, and
the Al composition ratio x in the second layer is 0.75 or more and 0.96 or less.

### Supplementary Description 8

The semiconductor laminate according to any one of supplementary descriptions 1 to 7,
in which the oxygen concentration in the third layer is 1×10¹⁶ cm⁻³ or less over the entire third layer excluding the region from the main surface of the third layer up to a depth of 200 nm.

### Supplementary Description 9

The semiconductor laminate according to any one of Supplementary descriptions 1 to 8,
in which the silicon concentration in the third layer is 1×10¹⁶ cm⁻³ or less over the entire third layer excluding the region from the main surface of the third layer up to a depth of 200 nm.

### Supplementary Description 10

The semiconductor laminate according to any one of Supplementary descriptions 1 to 9,
in which each of the iron concentration and the carbon concentration in the third layer is 1×10¹⁶ cm⁻³ or less over the entire third layer excluding the region from the main surface of the third layer up to a depth of 200 nm.

### Supplementary Description 11

The semiconductor laminate according to any one of Supplementary descriptions 1 to 10,
in which the amount of strain ε₃ of the third layer in the c-axis direction determined by formula (3) at 27° C. is −0.1% or more and less than −0.01%:

$${ε}_{3} = ( {c}_{3} - {c}_{GaN} ) / {c}_{GaN} \times 100 \qquad ( 3 )$$

where c₃ represents the c-axis length of the GaN crystal included in the third layer; and
c_{GaN} represents the c-axis length of a strain-free bulk GaN crystal.

### Supplementary Description 12

The semiconductor laminate according to any one of Supplementary descriptions 1 to 11, further including a fourth layer,
in which the fourth layer is provided on the third layer and includes a group III nitride crystal having a band gap wider than gallium nitride.

### Supplementary Description 13

A semiconductor element including, as at least a part of an active layer, the third layer in the semiconductor laminate according to any one of Supplementary descriptions 1 to 12.

### Supplementary Description 14

A semiconductor laminate production method, including:
(a) preparing a substrate including silicon carbide and having a main surface,
(b) growing, on the main surface of the substrate, a first layer including an aluminum nitride crystal,
(c) subjecting the first layer to an annealing treatment,
(d) growing, on the first layer, a second layer including a crystal of any of aluminum gallium nitride, aluminum indium nitride, and aluminum indium gallium nitride, and
(e) growing, on the second layer, a third layer including a gallium nitride crystal;
in which, in (c), the dislocation density in the main surface of the first layer is decreased through the annealing treatment of the first layer to be smaller than the dislocation density in the main surface of the first layer immediately after (b).

### Supplementary Description 15

The semiconductor laminate production method according to Supplementary description 14,
in which tensile strain is generated in the first layer in a direction along the main surface of the substrate at 27° C. after (c).

### Supplementary Description 16

The semiconductor laminate production method according to Supplementary description 14 or 15,
in which the third layer is grown such that tensile strain is generated in the third layer in a direction along the main surface of the substrate at 27° C. in (e).

### DESCRIPTION OF SIGNS AND NUMERALS

1: Semiconductor laminate (laminate)
2: Semiconductor element
10: Substrate
20: Base layer
30: Intermediate layer
40: Electron transport layer
50: Electron supply layer
60: Cap layer

1. A semiconductor laminate, comprising:
a substrate comprising silicon carbide and having a main surface,
a first layer provided on the main surface of the substrate, the first layer comprising an aluminum nitride crystal,
a second layer provided on the first layer, the second layer comprising a crystal of any of aluminum gallium nitride, aluminum indium nitride, and aluminum indium gallium nitride, and
a third layer provided on the second layer, the third layer comprising a gallium nitride crystal,
wherein the first layer has tensile strain in a direction along the main surface at 27° C.

2. The semiconductor laminate according to claim 1,
wherein the third layer has tensile strain in a direction along the main surface at 27° C.

3. The semiconductor laminate according to claim 1,
wherein the third layer has a thickness of 1 μm or less,
a full width at half maximum of (0002) diffraction from the third layer in X-ray rocking curve measurement is 300 arcseconds or less, and
a full width at half maximum of (10-12) diffraction from the third layer in X-ray rocking curve measurement is 410 arcseconds or less.

4. The semiconductor laminate according to claim 1,
wherein a dislocation density in a main surface of the third layer is 1×10⁹ cm⁻² or less.

5. The semiconductor laminate according to claim 1,
wherein the first layer has a thickness of 200 nm or more and 800 nm or less.

6. The semiconductor laminate according to claim 1,
wherein the second layer is coherently provided on the first layer.

7. The semiconductor laminate according to claim 1,
wherein the second layer comprises a crystal represented by a composition formula of AlₓGa₁₋ₓN, and
an Al composition ratio x in the second layer is 0.75 or more and 0.96 or less.

8. The semiconductor laminate according to claim 1,
wherein an oxygen concentration in the third layer is 1×10¹⁶ cm⁻³ or less over the entire third layer excluding a region from a main surface of the third layer up to a depth of 200 nm.

9. The semiconductor laminate according to claim 1,
wherein a silicon concentration in the third layer is 1×10¹⁶ cm⁻³ or less over the entire third layer excluding a region from a main surface of the third layer up to a depth of 200 nm.

10. The semiconductor laminate according to claim 1,
wherein each of an iron concentration and a carbon concentration in the third layer is 1×10¹⁶ cm⁻³ or less over the entire third layer excluding a region from a main surface of the third layer up to a depth of 200 nm.

11. The semiconductor laminate according to claim 1,
wherein an amount of strain E3 of the third layer in a c-axis direction determined by formula (3) at 27° C. is −0.1% or more and less than −0.01%:
$${ε}_{3} = ( {c}_{3} - {c}_{GaN} ) / {c}_{GaN} \times 100 \qquad ( 3 )$$
where c₃ represents a c-axis length of the gallium nitride crystal included in the third layer; and
c_{GaN} represents a c-axis length of a strain-free bulk gallium nitride crystal.

12. A semiconductor element comprising, as at least a part of an active layer, the third layer in the semiconductor laminate according to claim 1.

13. A semiconductor laminate production method, comprising:
(a) preparing a substrate comprising silicon carbide and having a main surface,
(b) growing, on the main surface of the substrate, a first layer comprising an aluminum nitride crystal,
(c) subjecting the first layer to an annealing treatment,
(d) growing, on the first layer, a second layer comprising a crystal of any of aluminum gallium nitride, aluminum indium nitride, and aluminum indium gallium nitride, and
(e) growing, on the second layer, a third layer comprising a gallium nitride crystal;
wherein, in (c), a dislocation density in a main surface of the first layer is decreased through the annealing treatment of the first layer to be smaller than a dislocation density in the main surface of the first layer immediately after (b).
